(19) United States
(12) Patent Application Publication
(10) Pub. No.: US 2026/0223476 A1
(43) Pub. Date: Jul. 30, 2026

(54) COMPRESSION ROLLER FOR WIRE BONDING SUBSTRATES

(71) Applicant: Maxeon Solar Pte. Ltd., Singapore (SG)

(72) Inventors: RICHARD HAMILTON SEWELL, Los Altos, CA (US); COLIN MARTIN, Soquel, CA (US); SAGAR DALVI, Fremont, CA (US); TODD R. JOHNSON, San Jose, CA (US); MATTHIEU REICH, San Jose, CA (US); ANJULI WRIGHT, San Jose, CA (US)

(21) Appl. No.: 19/452,125

(22) Filed: Jan. 16, 2026

Related U.S. Application Data
(60) Provisional application No. 63/751,795, filed on Jan. 30, 2025.

(51) Int. Cl. H10F 71/00; B30B 3/00; H10F 77/00

(52) U.S. Cl. CPC H10F 71/1375; B30B 3/005; H10F 77/937

(57) ABSTRACT

Embodiments described herein relate to an apparatus that includes a first roller with a plurality of first grooves, and a force application assembly configured to apply a force to the first roller. In an embodiment, the apparatus further comprises a frame, where the first roller is displaceable in a vertical direction along the frame. In an embodiment, the apparatus further includes a second roller that is coupled to the first roller, where the second roller includes a plurality of second grooves, and where the plurality of first grooves are aligned with the plurality of second grooves.

### CROSS-REFERENCE TO RELATED APPLICATIONS

This application claims benefit of U.S. Provisional Patent Application No. 63/751,795, filed on Jan. 30, 2025, the entire contents of which are hereby incorporated by reference herein.

### BACKGROUND

### 1) Field

Embodiments relate to the field of renewable energy, and in particular, include compression rollers for wire bonding substrates.

### 2) Description Of Related Art

Semiconductor Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Electrical conversion efficiency is an important characteristic of a solar cell as it is directly related to the capability of the solar cell to generate power; with higher efficiency providing additional value to the end customer; and, with all other things equal, higher efficiency also reduces manufacturing cost per Watt. Likewise, simplified manufacturing approaches provide an opportunity to lower manufacturing costs by reducing the cost per unit produced. Accordingly, techniques for increasing the efficiency of solar cells and techniques for simplifying the manufacturing of solar cells are generally desirable.

### BRIEF DESCRIPTION OF THE DRAWINGS

FIGS. 1A-1C illustrate plan views of various stages in a metallization and stringing method for back-contact solar cells, in accordance with an embodiment of the present disclosure.

FIG. 2 illustrates a string of solar cells, in accordance with an embodiment of the present disclosure.

FIG. 3A illustrates a side view of a wire feed and bonding system, in accordance with an embodiment of the present disclosure.

FIG. 3B illustrates a plan view of a wire feed and bonding system that shows the grooves on the feed roller and the compression roller, in accordance with an embodiment of the present disclosure.

FIG. 4A illustrates a front view of a compression bonding tool with a compression roller with independent force control on each end of the compression roller, in accordance with an embodiment of the present disclosure.

FIG. 4B illustrates a side view of a compression bonding tool with a compression roller and a feed roller, in accordance with an embodiment of the present disclosure.

FIGS. 5A-5H illustrates side views of a process for wire bonding solar cells with a continuous process, in accordance with an embodiment of the present disclosure.

FIGS. 5I-5P illustrate a process to fold a busbar behind the substrate after wire bonding, in accordance with an embodiment of the present disclosure.

FIG. 6 illustrates a side view of a compression bonding tool that includes a cam for vertically displacing a compression roller at a desired time, in accordance with an embodiment of the present disclosure.

FIG. 7 illustrates a side view of a compression bonding tool that includes a wedge that may be actuated to vertically displace a compression roller, in accordance with an embodiment of the present disclosure.

FIG. 8A illustrates a plan view of a chuck with a protrusion to raise a compression roller at a desired location, in accordance with an embodiment of the present disclosure.

FIG. 8B illustrates a cross-sectional view of the chuck in FIG. 8A along line B-B', in accordance with an embodiment of the present disclosure.

FIGS. 9A-9D illustrate a compression bonding tool with a compression roller that has one or more lobes for raising the compression roller at desired times during a wire bonding process.

FIGS. 10A-10D illustrate compression bonding tools that comprise one or more sprayers for applying a lubricant to a compression roller during operation of the compression bonding tools, in accordance with an embodiment of the present disclosure.

### DETAILED DESCRIPTION

Wire-based metallization and stringing techniques for solar cells, and the resulting solar cells, modules, and equipment used to provide the wire-based metallization on a chuck surface with a compression bonding tool, are described herein. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

The following detailed description is merely illustrative in nature and is not intended to limit the embodiments or the application and uses of such embodiments. As used herein, the word “exemplary” means “serving as an example, instance, or illustration.” Any implementation described herein as exemplary is not necessarily preferred or advantageous over other implementations. Furthermore, there is no intention to be bound by any expressed or implied theory presented in the preceding technical field, background, brief summary or the following detailed description.

References to “one embodiment” or “an embodiment.” do not necessarily refer to the same embodiment. Particular features, structures, or characteristics can be combined in any suitable manner consistent with this disclosure.

Terminology. The following paragraphs provide definitions and/or context for terms found in this disclosure (including the appended claims):

“Comprising” is open-ended term does not foreclose additional structure or steps.

“Configured to” connotes structure by indicating that a device, such as a unit or a component, includes structure that performs a task or tasks during operation, such structure is configured to perform the task even when the device is not currently operational (e.g., is not on/active). A device “configured to” perform one or more tasks is expressly intended to not invoke a means or step plus function interpretations under 35 U.S.C. § 112, (f) or sixth paragraph.

“First,” “second,” etc. terms are used as labels for nouns that they precede, and do not imply any type of ordering (e.g., spatial, temporal, logical, etc.). For example, reference to a “first” solar cell does not necessarily mean such solar cell in a sequence; instead, the term “first” is used to differentiate this solar cell from another solar cell (e.g., a “second” solar cell).

“Coupled” refers to elements, features, structures or nodes unless expressly stated otherwise, that are or can be directly or indirectly joined or in communication with another element/node/feature, and not necessarily directly mechanically joined together.

“Inhibit” describes reducing, lessening, minimizing or effectively or actually eliminating something, such as completely preventing a result, outcome or future state completely.

“Doped regions,” “semiconductor regions,” and similar terms describe regions of a semiconductor disposed in, on, above or over a substrate. Such regions can have a N-type conductivity or a P-type conductivity, and doping concentrations can vary. Such regions can refer to a plurality of regions, such as first doped regions, second doped regions, first semiconductor regions, second semiconductor regions, etc. The regions can be formed of a polycrystalline silicon on a substrate or as portions of the substrate itself.

“Thin dielectric layer,” “tunneling dielectric layer,” “dielectric layer,” “thin dielectric material” or intervening layer/material refers to a material on a semiconductor region, between a substrate and another semiconductor layer, or between doped or semiconductor regions on or in a substrate. In an embodiment, the thin dielectric layer can be a tunneling oxide or nitride layer of a thickness of approximately 2 nanometers or less. The thin dielectric layer can be referred to as a very thin dielectric layer, through which electrical conduction can be achieved. The conduction can be due to quantum tunneling and/or the presence of small regions of direct physical connection through thin spots in the dielectric layer. Exemplary materials include silicon oxide, silicon dioxide, silicon nitride, and other dielectric materials.

“Intervening layer” or “insulating layer” describes a layer that provides for electrical insulation, passivation, and inhibit light reflectivity. An intervening layer can be several layers, for example a stack of intervening layers. In some contexts, the insulating layer can be interchanged with a tunneling dielectric layer, while in others the insulating layer is a masking layer or an “antireflective coating layer” (ARC layer). Exemplary materials include silicon nitride, silicon oxynitride, silicon dioxide, aluminum oxide, amorphous silicon, polycrystalline silicon, molybdenum oxide, tungsten oxide, indium tin oxide, tin oxide, vanadium oxide, titanium oxide, silicon carbide and other materials. In an example, the intervening layer can include a material that can act as a moisture barrier. Also, for example, the insulating material can be a passivation layer for a solar cell.

“Substrate” can refer to, but is not limited to, semiconductor substrates, such as silicon, and specifically such as single crystalline silicon substrates, multi-crystalline silicon substrates, wafers, silicon wafers and other semiconductor substrates used for solar cells. In an example, such substrates can be used in micro-electronic devices, photovoltaic cells or solar cells, diodes, photo-diodes, printed circuit boards, and other devices. These terms are used interchangeably herein.

“About” or “approximately”. As used herein, the terms “about” or “approximately” in reference to a recited numeric value, including for example, whole numbers, fractions, and/or percentages, generally indicates that the recited numeric value encompasses a range of numerical values (e.g., +/−5% to +/−10% of the recited value) that one of ordinary skill in the art would consider equivalent to the recited value (e.g., performing substantially the same function, acting in substantially the same way, and/or having substantially the same result).

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Disclosed herein are solar cells. In one embodiment, a substrate may include a back surface and an opposing light-receiving surface. A plurality of semiconductor regions is disposed in or above the back surface of the substrate. A conductive contact structure is disposed on the semiconductor regions. The conductive contact structure includes a plurality of conductive wires, each conductive wire of the plurality of conductive wires essentially continuously bonded directly to a corresponding one of semiconductor regions. In an additional embodiment, each conductive wire of the plurality of conductive wires can be bonded through a metal layer to one of the semiconductor regions. In an example, the metal layer can be a metal seed layer. In an embodiment, each conductive wire of the plurality of conductive wires can be a non-coated conductive wire. In one example, the conductive contact structure can include a non-coated conductive wire or a plurality of non-coated conductive wires.

Also, disclosed herein are strings of solar cells. In one embodiment, a string of solar cells includes a plurality of solar cells, such as back-contact solar cells or front contact solar cells. Each of the plurality of back-contact solar cells includes P-type and N-type doped diffusion regions. A plurality of conductive wires is disposed over a back surface of each of the plurality of solar cells, wherein each of the plurality of wires is substantially parallel to the P-type and N-type doped diffusion regions of each of the plurality of solar cells. Every other one of the plurality of wires is cut in a region between each adjacent pair of the plurality of solar cells.

Also disclosed herein are methods of fabricating strings of solar cells. In one embodiment a method of electrically coupling solar cells involves aligning conductive wires over the back sides of adjacent solar cells. The wires are aligned substantially parallel to P-type and N-type doped diffusion regions of the solar cells. The method involves bonding the wires directly to the back side of each of the solar cells over the P-type and N-type doped diffusion regions using thermocompression bonding, ultrasonic bonding, or thermosonic bonding.

Also disclosed herein are wire bonding systems for electrically coupling solar cells. In one embodiment, a wire bonding system includes one or more of a creel assembly containing a plurality of wire spools, a coarse pitch assembly with a plurality of coarse pitch combs, a fine pitch comb, a feed roller, and a compression roller. Various capstans, rollers, and/or the like may be provided within the wire bonding system to control tension of wires that are fed through the wire bonding system. In an embodiment, one or both of the feed roller or the compression roller may comprise grooves that are configured to align conductive wires substantially parallel with P-type and N-type doped diffusion regions of each of the solar cells in order to bond the wires to the back side of each of the solar cells over the P-type and N-type doped diffusion regions.

Embodiments disclosed herein include the wire bonding for solar substrates with a continuous manufacturing process. In an embodiment, the process may include placing a plurality of substrates in a line on a series of hot chucks and moving the chucks under the compression roller such that the wire is continuously bonded from one substrate to the next substrate. This allows for forming a string that can be cut to size after wire bonding. In an embodiment, force is applied to the compression roller through one or more different mechanisms, such as a motorized actuator (e.g., a servo motor), a hydraulic press, or the like. In some embodiments, uniform compression across the compression roller may be enabled through the use of two independent force application systems. The force application systems may be applied to each end of the compression roller or to the journals on either side of the compression roller.

In an embodiment, the compression roller may have variable control systems in order to modulate the force applied to the substrates. For example, when wire is bonded to a trailing edge of a substrate, the pressure may spike if the force on the compression roller is kept constant. Similarly, wire bonding the leading edge of the substrate may result in pressure non-uniformities against the substrate. Accordingly, embodiments may include systems and/or processes for force modulation. For example, a servo motor with closed loop control may be used. Mechanical solutions, such as cams or wedges, may also be used.

Embodiments disclosed herein may also include a sprayer system for applying lubricant or non-stick coatings to the compression roller. The sprayer system may be configured so that the lubricant can be applied to the compression roller during operation of the compression roller. This minimizes the down time needed for maintenance. In an embodiment, one or more spray nozzles may be directed towards a surface of the compression roller. The nozzles may be stationary, or the one or more nozzles may be displaced across the surface of the compression roller in a direction parallel to the surface of the compression roller. For example, the displaced nozzle may apply a coating with a spiral pattern over the roller. The pitch of the spiral pattern may be chosen such that the spray is re-deposited on the same portion of the roller again after it has worn off. A number of nozzles may be chosen such that an entire surface of the roller remains coated at any given time.

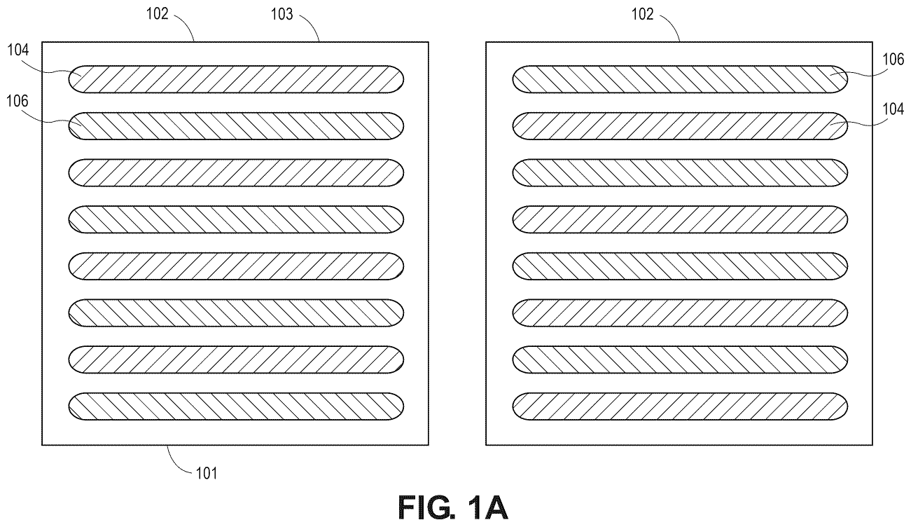

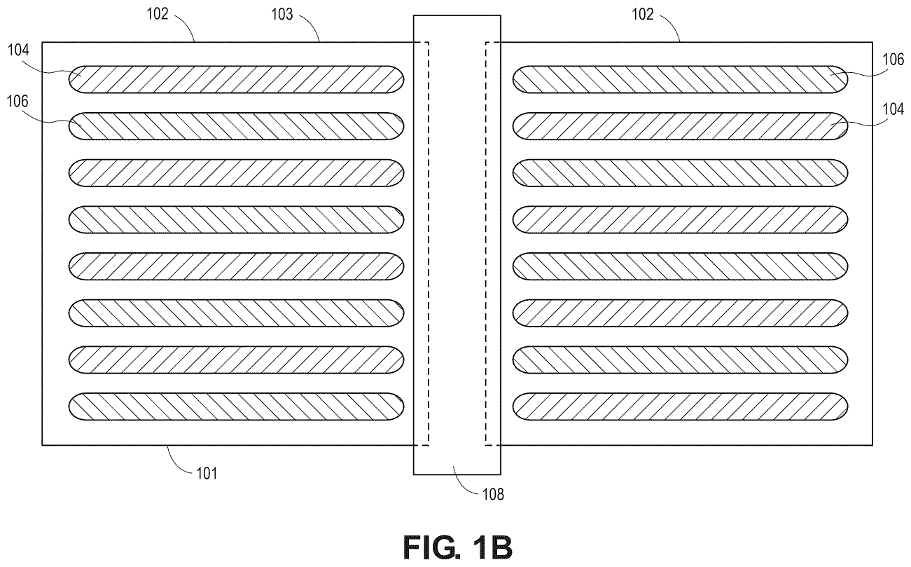

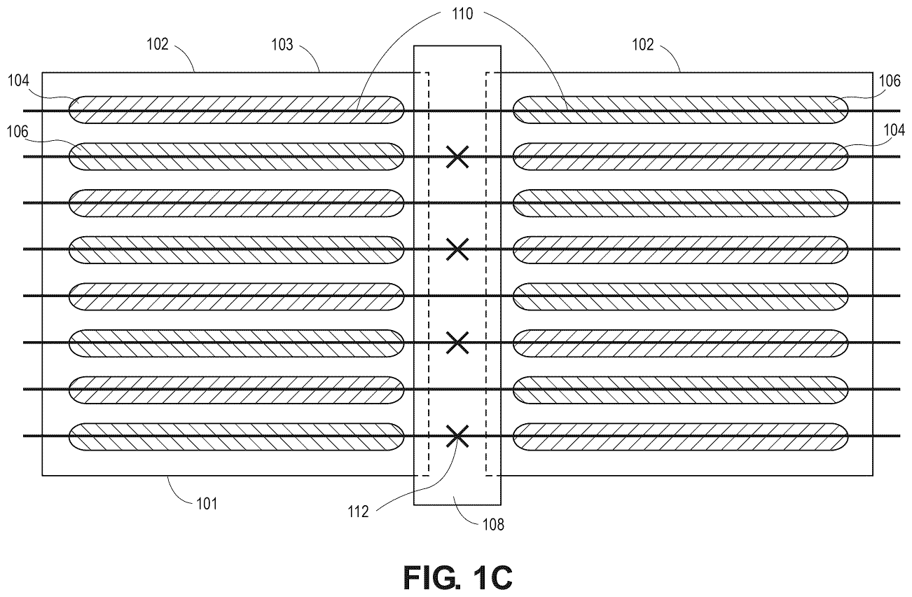

FIGS. 1A-1C illustrate plan views of various stages in a metallization and stringing method for back-contact solar cells, in accordance with an embodiment of the present disclosure.

FIG. 1A illustrates a back-side view of adjacent solar cells 102 that are to be stringed together, including alternating P-type doped diffusion regions 104 and N-type doped diffusion regions 106. In one such embodiment, each of the plurality of solar cells 102 is substantially rectangular, and the P-type doped diffusion regions 104 and the N-type doped diffusion regions 106 are substantially parallel to the edges 101, 103 of the solar cells 102. A solar cell that is substantially rectangular could be, for example, a square, or another rectangular shape, and can have standard, cut, or rounded corners. As illustrated in FIG. 1A, the solar cells 102 are asymmetric in the sense that the solar cells 102 end with a P finger on one side (e.g., side 103) and an N finger on the opposite side (e.g., side 101). The asymmetric solar cells can then be placed in alternating orientations along the string, as illustrated in FIG. 1A. The asymmetric solar cell design together with the alternating orientations along the string enable the use of wires that are parallel to the edges 101, 103 of the solar cells because the P finger on one of the solar cells is directly across from the N finger of the adjacent solar cell, as is explained below with respect to FIG. 1C. Referring to FIG. 1B, a method of metallization and stringing includes

attaching a non-conductive shield, tape or paint strip 108 to the back sides of the adjacent solar cells 102. The non-conductive shield, tape or paint strip 108 can serve to hide the wires when viewed from the front. In some embodiments, non-conductive shield, tape or paint strip 108 is applied to the adjacent solar cells 102 before the conductive wires 110 are applied. In other embodiments, the conductive wires are bonded to the adjacent solar cells 102 so that the conductive wires 110 are not bonded up to edges of the solar cells 102. In such an embodiment, the non-conductive shield, tape or paint strip 108 is then inserted between the back of the solar cells 102 and the conductive wires 110. In yet another embodiment, the non-conductive shield, tape or paint strip 108 may be placed on the sunny side (i.e., the top side of the adjacent solar cells 102). Thus, the non-conductive shield covers exposed sections of the wires between each adjacent pair of the plurality of solar cells. Therefore, according to embodiments, the non-conductive shield, tape or paint strip 108 includes a material that is substantially opaque to sufficiently cloak the wires when viewed from the front. The non-conductive shield, tape or paint strip 108 can also assist in alignment of the solar cells, and/or holding the solar cells 102 together. The non-conductive shield, tape or paint strip 108 can include materials such as polypropylene or polyethylene and can further include an adhesive layer like an acrylate. A non-conductive shield, tape or paint strip 108 with an adhesive layer can be beneficial to assist in alignment. Although a non-conductive shield, tape or paint strip 108 can be beneficial for the reasons explained above, other embodiments do not include a non-conductive shield (e.g., the non-conductive shield 108 can be optional).

Referring to FIG. 1C, the method of metallization and stringing includes aligning conductive wires 110 over the back sides of adjacent solar cells 102. As shown in FIG. 1C, the non-conductive shield, tape or paint strip 108 is present during the conductive wire 110 bonding. In other embodiments, the non-conductive shield, tape or paint strip 108 may be applied after the conductive wires 110 are bonded to the solar cells 102. In one embodiment, the wires 110 are aligned substantially parallel to the P-type doped diffusion regions 104 and N-type doped diffusion regions 106 of the solar cells 102. The wires 110 can have a cross-sectional shape that is round, flattened, slightly flattened, or another shape. Round wires can be beneficial because they can be rolled or twisted. In an embodiment involving the alignment and placement of round wires, the wires can be flattened prior to or during bonding the wires to the back side of each of the solar cells.

Conductive wires include an electrically conducting material (e.g., a metal such as aluminum, copper or another suitable conductive material), with or without a coating such as tin, silver, or nickel. In an embodiment, an organic solderability protectant is not used on the wires. In another embodiment, an organic solderability protectant is used on the wires. In the embodiment illustrated in FIG. 1C, the number of wires is equal to (or substantially equal to) the number of diffusion regions of each of the plurality of solar cells. In one example, the number of wires can be approximately between 5-15 wires, between 10-20 wires, between 15-25 wires, between 20-30 wires, between 25-35 wires, between 30-40 wires, between 35-45 wires, between 10-50 wires, or greater than 50 wires. In one such embodiment, a single wire is aligned over each of the P-type doped diffusion regions 104 and N-type doped diffusion regions 106 of the solar cells 102. According to one embodiment, each of the wires 110 is roughly centered over one of the P-type doped diffusion regions 104 and N-type doped diffusion regions 106 of the solar cells 102. As illustrated in FIG. 1C, the wires 110 can be aligned so that they are substantially parallel to the edges 101, 103 of the plurality of solar cells 102.

Referring again to FIG. 1C, the wires 110 can be aligned via a variety of mechanisms. For example, in one embodiment, aligning the conductive wires 110 over the back sides of adjacent solar cells 102 involves use of a grooved roller or a bond head. Other mechanisms can be used to align the conductive wires 110 over the P-type doped diffusion regions 104 and N-type doped diffusion regions 106 of the solar cells 102 instead of, or in addition to, a grooved roller or a bond head. For example, according to one embodiment, a reed, or other mechanism suitable for aligning and guiding the conductive wires can be used. When aligning wires over a solar cell that is not the first solar cell, the presence of wires bonded to the first solar cell can assist in alignment of the wires over the subsequent solar cells, in accordance with an embodiment.

After aligning the conductive wires 110, the conductive wires are bonded to the back side of the solar cells 102 the P-type doped diffusion regions 104 and N-type doped diffusion regions 106 of the solar cells 102, e.g., using thermocompression bonding or ultrasonic bonding approaches as described herein. Referring again to FIG. 1C, according to one embodiment, the method of metallization and stringing includes cutting every other one of the wires 110 between each adjacent pair of the solar cells 102. As illustrated in FIG. 1C, the wires 110 are cut at the locations 112, such that all of the wires connected to the P-type diffusion on one side of a solar cell 102, and all of the wires connected to the N-type diffusion of the opposite side of the solar cell are cut.

Prior to cutting the wires 110 in the locations 112, the pair of solar cells are shorted. Cutting the wires 110 enables electrically coupling the solar cells for collection of current from the solar cell string. Cutting the wires 110 in the locations 112 can involve any wire cutting technique. For example, the wires 110 can be cut in the locations 112 with a laser or a blade. Although the FIGS. 1A-1C illustrate only two solar cells, a solar cell string can include any number of solar cells stringed together (e.g., 2 or more solar cells stringed together). The process is continuous in the sense that arbitrarily long strings of solar cells can be made.

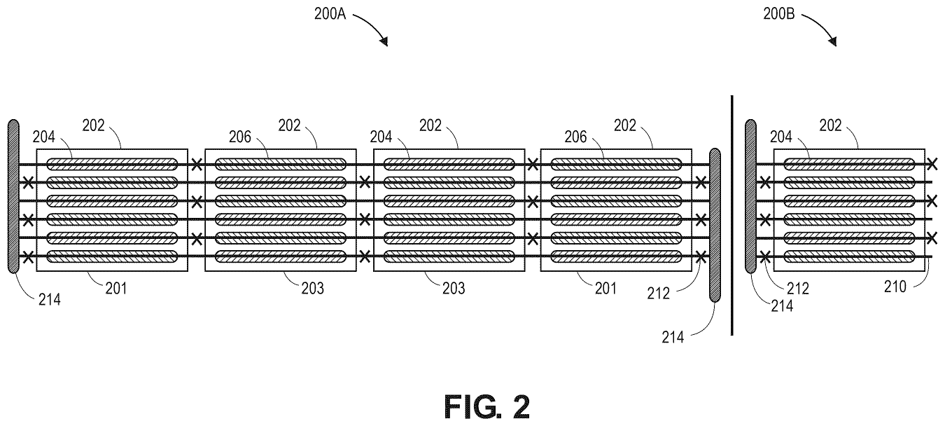

FIG. 2 illustrates one example of a string of solar cells, in accordance with an embodiment of the present disclosure. The solar cell string 200A illustrated in FIG. 2 includes a plurality of solar cells 202 that are electrically coupled together in series. The solar cell string 200A has two end solar cells 201, and inner solar cells 203 connected in series between the two end solar cells 201. Each of the two end solar cells 201 is electrically coupled with a busbar 214. At each of the end solar cells 201, every other one of the wires is coupled with a busbar 214 to couple only one of the two electrodes of the end solar cell, either the P-type doped diffusion regions 204 or the N-type doped diffusion regions 206. In one embodiment, the coupling of every other one of the wires from an end solar cell 201 with a busbar 214 can be achieved by first cutting all the wire at each end of the string and connecting only the wires for either the P-type or N-type doped diffusion regions. Alternatively, all the wires for an end solar cell 201 can first be connected to a busbar 214, and then every other wire can be cut in the locations 212.

Only the end solar cells 201 are connected to a busbar 214, in contrast to other stringing techniques which can involve attaching busbar(s) to each solar cell, according to some embodiments. Though, embodiments may also include busbars 214 between each solar cell 201 as well. The busbars 214 can couple the solar string 200A with another solar string (e.g., such as the solar string 200B), or to another circuit (e.g., a circuit outside the module through a junction box).

As illustrated in FIG. 2, in one embodiment, a given cut section of wire is to electrically couple at most two solar cells together in series, wherein the P-type doped diffusion area of one of the two solar cells is connected to the N-type doped diffusion area of the other solar cell. However, other embodiments can include more than two solar cells being coupled together with a given cut section of wire. For example, if solar cells are connected in parallel, it is possible to connect more than two cells with a given cut section of wire. Also as illustrated in FIG. 2, in one embodiment, a cut section of wire that electrically couples an end solar cell 201 to the busbar 214 couples a single solar cell to the busbar 214. However, as mentioned above, in embodiments that connect solar cells in parallel, a given cut section of wire can connect more than a single solar cell to the busbar. Thus, a solar string can be created using the plurality of wires 210 by aligning and bonding the wires over the P-type and N-type doped diffusion regions of each of the solar cells, followed by cutting some of the wires to achieve the desired configuration of solar cells in a string.

Thus, in accordance with one or more embodiments of the present disclosure, a stringing method provides a structure having compressed wires against one or more solar cells. In an embodiment, every second wire is cut between wafers and busbars at ends.

As can be appreciated, aligning and bonding the number of wires to the proper diffusion regions in a high-volume assembly environment is a complex task. Accordingly, embodiments disclosed herein include a wire feed and bonding system. The wire feed and bonding system allows for a plurality of electrically conductive wires to be fed from a plurality of spools to specified grooves on a compression roller. The grooves on the compression roller are configured to be aligned with different diffusion regions on a solar cell. A plurality of solar cells that are secured to one or more chucks may pass below the compression roller (e.g., on a conveyor and/or track based system), and the wires are bonded to each solar cell as the solar cells pass below the compression roller. In some embodiments, the wires are bonded to diffusion regions of each solar cell, to poly-silicon regions of each solar cell, or any other desired location along the solar cell.

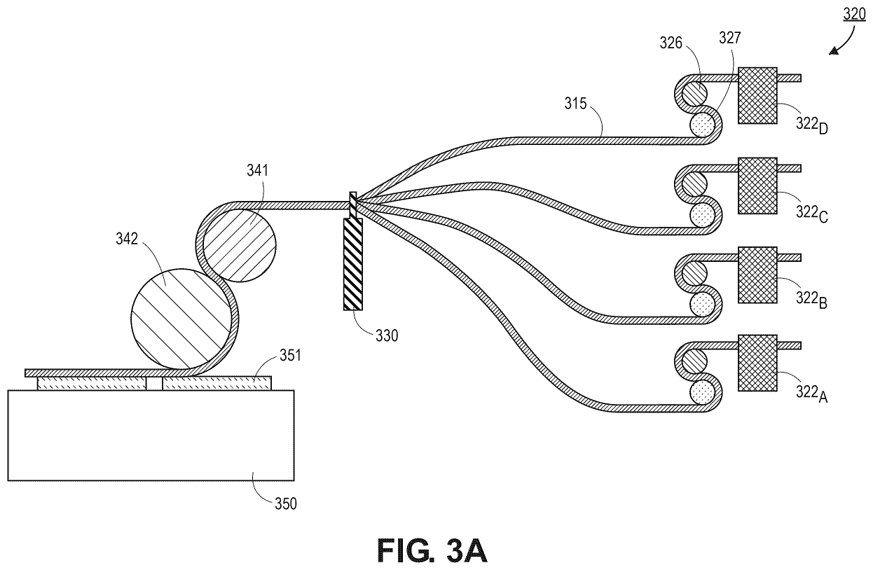

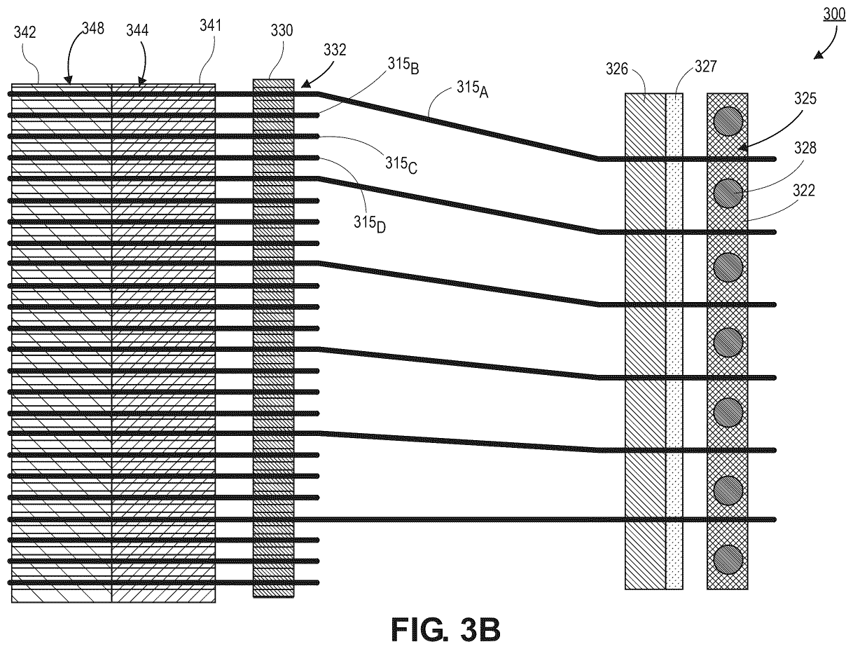

Referring now to FIG. 3A, a cross-sectional illustration of a wire feed system 320 that guides a plurality of electrically conductive wires 315 to a feed roller 341 and a compression roller 342 is shown, in accordance with an embodiment. The wires 315 may comprise any electrically conductive material that is suitable for being wire bonded to solar cells. One or more embodiments described herein may include an aluminum wire. It is to be appreciated that, in some embodiments, aluminum wires 315 are preferred since they can be subjected to thermocompression bonding at a temperature in a range of approximately 300-450 degrees Celsius, or lower with the inclusion of ultrasonic energy. In a particular example, the bonding temperature can include approximately 350 degrees Celsius. By contrast, a copper wire may need to be heated to substantially higher temperatures for thermocompression bonding and, as a result, can cause a silicon substrate to bow upon cooling after bonding to the silicon substrate. It is also to be appreciated that excessive bowing with copper wires can result from the fact that copper has a higher yield strength than pure aluminum.

On cooling, both aluminum and copper will contract to drive wafer bowing, but the degree of contraction in aluminum is limited by the low yield strength. Many aluminum alloys have higher yield strength (e.g., 241 MPA for AL6061) while pure aluminum has a yield strength of 11 MPA. Accordingly, in some embodiments, pure or essentially pure aluminum wires are used for forming a metallization layer for silicon based solar cells to enable low bowing. Additionally, the lower yield strength allows for lower forces to plastically deform the wire, which is beneficial for thermocompression bonding. In an example, the aluminum wires do not include any additional coating or layer. Copper may also form thick oxides in air at the high temperatures required for thermocompression bonding, whereas an oxide of aluminum is self-limiting. However, in other embodiments, copper wires or any other wire material described herein (with or without a coating) may be used for forming a metallization layer for solar cells with the wire feed and bonding system 300.

In an embodiment, the spools (not shown) may feed wires 315 to a coarse pitch assembly that comprises a plurality of coarse pitch combs 322. In the illustrated embodiment, four coarse pitch combs 322_{A}-322_{D} are oriented in a vertical stack. Though, the coarse pitch combs 322 may be provided with any spatial positioning.

In an embodiment, each of the coarse pitch combs 322 may comprise a plurality of channels or slots (out of the plane of FIG. 3A). In an embodiment, a pitch of the channels may be an integer multiple of the desired final pitch. In a particular embodiment, the integer multiple is equal to the number of coarse pitch combs 322 provided in the wire feed system 320. For example, in FIG. 3A the pitch of the channels 325 may be approximately four times the desired final pitch of the wires 315. In a particular embodiment, the pitch of the channels 325 may be between approximately 1 mm and approximately 5.0 mm. For example, the pitch of the channels may be approximately 2.0 mm. Though, it is to be appreciated that smaller or larger pitches may also be used for the channels in other embodiments.

In an embodiment, the wires 315 may be routed from the coarse pitch combs 322 to a single fine pitch comb 330. The fine pitch comb 330 may align the wires 315 into a single horizontal plane. The fine pitch comb 330 may have a plurality of channels (out of the plane of FIG. 3A) that are spaced at a fine pitch that is smaller than the coarse pitch. In an embodiment, the fine pitch is substantially equal to the pitch of grooves (not shown) on the compression roller 342. For example, the fine pitch may be between 0.1 mm and 1.0 mm. In the case of a coarse pitch of approximately 2.0 mm with four coarse pitch combs 322, the fine pitch may be approximately 0.5 mm.

In an embodiment, the wires 315 may at least partially wrap around one or more rollers between the coarse pitch combs 322 and the fine pitch comb 330. For example, each wire 315 may pass through a driven capstan roller 326 and an idle roller 327. The driven capstan roller 326 may be driven by a motor or the like. The idle roller 327 may spin passively as wire 315 is drawn through the system. The driven capstan roller 326 allows for the tension in the wire 315 to be decreased before reaching the fine pitch comb 330. That is, the tension in the wires 315 between spools in a creel assembly and the coarse pitch combs 322 may be higher than a tension in the wires 315 between the coarse pitch combs 322 and the fine pitch comb 330. While a roller assembly with two rollers (e.g., driven capstan roller 326 and idle roller 327) is shown, embodiments may include one or more rollers, or rollers may be omitted from the system 300.

In an embodiment, the wires 315 may be routed from the coarse pitch combs 322 to the fine pitch comb 330 through the use of transfer caps (not shown in FIG. 3A). Each transfer cap may have slots that receive the ends of each wire 315 of a given coarse pitch comb 322, and the transfer cap delivers the wires 315 to the fine pitch comb 330. Each of the transfer caps may be offset from each other by one fine pitch. This allows for the wires 315 from all of the coarse pitch combs 322 to be interleaved with each other at the fine pitch comb 330 in an orderly manner.

As shown, the wires 315 that exit the fine pitch comb 330 may partially wrap around the feed roller 341 and partially wrap around the compression roller 342. The compression roller 342 may compress the wires 315 against substrates 351, such as wafers comprising solar cells. For example, the substrates 351 may comprise solar cells similar to any of the solar cells described in greater detail herein. As a chuck 350 is displaced relative to the compression roller 342, the wires 315 are bonded across the substrates 351 to provide an electrically connected string of solar cells, similar to any of the string of solar cells described in greater detail herein. A more detailed description of the chuck 350 is provided in greater detail herein. In an embodiment, the compression roller 342 may be pressed against the substrates with a force sufficient to provide thermocompression bonding between the wires 315 and the substrates 351 at a desired temperature.

Referring now to FIG. 3B, a plan view illustration of a portion of a wire feed and bonding system 300 is shown, in accordance with an embodiment. In an embodiment, the entire length of wires 315_{A} from the coarse pitch comb 322 to the compression roller 342 is shown. The remaining wires 315_{B}-315_{D} extend from the compression roller 342 to the fine pitch comb 330. Thereafter, wires 315_{B}-315_{D} extend out of the plane of FIG. 3B to coarse pitch combs 322 above or below the illustrated coarse pitch comb 322.

In an embodiment, the coarse pitch comb 322 may be similar to any of the coarse pitched combs described in greater detail herein. For example, the coarse pitch comb 322 may comprise a plurality of round pins 328 that define coarse pitch channels 325. The wires 315_{A} may then wrap through a driven capstan roller 326 and an idle roller 327 before being inserted into the slots 332 of the fine pitch comb 330. As shown, the wires 315_{A} are placed at every fourth slot 332. In an embodiment, the fine pitch comb 330 may be similar to any of the fine pitch combs described in greater detail herein.

In an embodiment, the wires 315_{A}-315_{D} may pass from the fine pitch comb 330 into grooves 344 that are formed on a surface of the feed roller 341. The grooves 344 may have a depth that is greater than the diameter of the wires 315. The wires 315 are then fed into the grooves 348 of the compression roller 342. The grooves 348 and the grooves 344 may have substantially the same pitch when the system 300 is operating and/or the feed roller 341 and the compression roller 342 are at a desired operating temperature.

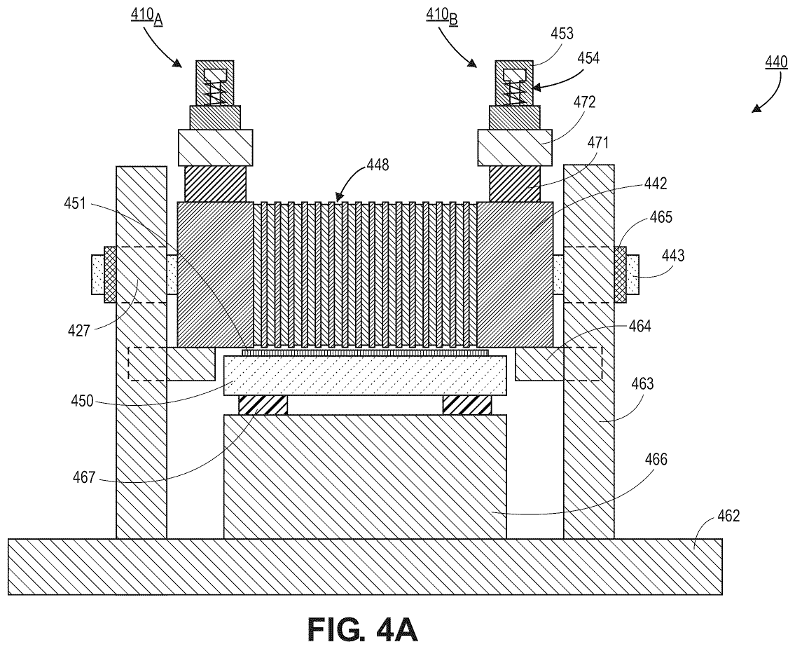

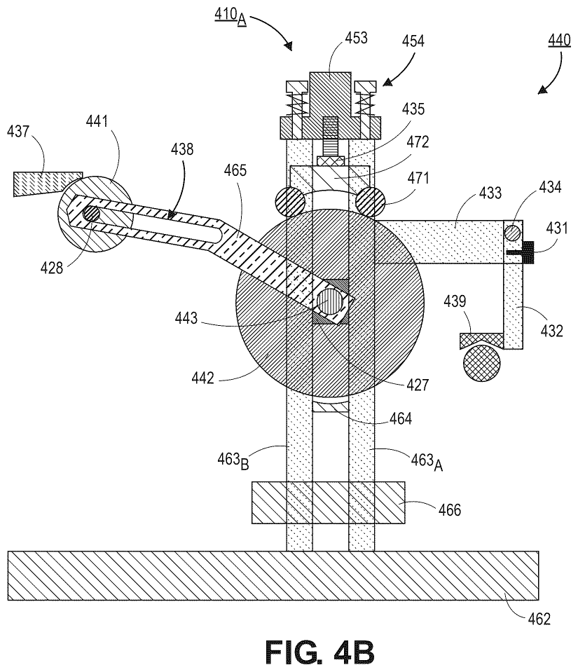

Referring now to FIGS. 4A and 4B, illustrations of a compression roller assembly 440 are shown, in accordance with an embodiment. FIG. 4A is a front view of the compression roller assembly 440, and FIG. 4B is a side view of the compression roller assembly 440. As shown, the compression roller 442 may be a cylindrical roller with a plurality of grooves 448 to orient and align wires (not shown) during the compression bonding process. For example, wires set into the grooves 448 may be pressed against a substrate 451 that is supported on a chuck 450 that passes below the compression roller 442. In an embodiment, the chuck 450 may be displaced along a path by rollers, linear guides 467, or the like. The linear guides 467 may be coupled to a roller station 466 or other support. The roller station 466 may be coupled to a chassis 462 and/or frame 463 that supports the compression roller 442.

In an embodiment, journals 443 of the compression roller 442 may pass between parallel vertical frames 463_{A} and 463_{B}, as shown in FIG. 4B. A journal bearing 427 may secure the journals 443 to the vertical frames 463_{A} and 463_{B}, while allowing for rotation of the compression roller 442. In some embodiments, a roller cradle 464 may support outer edges of the compression roller 442 when the compression roller 442 is not engaged with the substrate during a bonding operation. As shown in FIG. 4B, the roller cradle 464 may have a curved surface that substantially matches a curvature of the compression roller 442. In an embodiment, the roller cradle 464 may be used to change a vertical position of the compression roller 442.

In an embodiment, a force application assembly 410 may generate a force that is applied to the compression roller 442 (e.g., directly, or through other components). In a particular embodiment, a plurality of force application assemblies 410 are used to allow for greater control of process uniformity. For example, in FIG. 4A a first force application assembly 410_{A} and a second force application assembly 410_{B} are provided on opposite ends of the compression roller 442. The use of independently controllable force application assemblies 410 allows for different magnitudes of the force to be applied to each end of the compression roller 442. This may be beneficial to account for any known existing process non-uniformities in the substrates that are being bonded, as a result of non-uniform wear on one or more components of the compression roller assembly 440, any tilt of the chuck 450 or the supporting structure, or for any other suitable reason.

In the illustrated embodiment, the force application assemblies 410 comprise contact surface bearings 471 that are coupled to a force plate 472 that apply the force to the compression roller 442. In an embodiment, a load cell 435 may be pressed against the force plate 472 by a press actuator 453. The load cell 435 may be used measure the force applied by the press actuator 453. In an embodiment, the load cell 435 may be replaced (or used in conjunction with) any other force sensing component and/or system. The load cell 435 may be coupled to a controller (not shown) in order to provide a measure of the force applied to the compression roller 442. In some embodiments, the controller may include a feedback control algorithm (e.g., a closed loop control algorithm) in order to provide a desired level of force to the compression roller 442.

The press actuator 453 may comprise a spring mechanism 454 as part of system used to generate the desired force. In other embodiments, the force application assembly 410 may comprise any suitable force generating option. For example, a motorized actuator (e.g., a servo motor), a hydraulic press, or the like may be used to apply a force against a face of the compression roller 442. In the illustrated embodiment, force application assemblies 410 apply a force directly to the compression roller 442. Other embodiments may include a force application assemblies 410 that apply a force to the journals 443 of the compression roller 442.

FIG. 4B also illustrates a feed roller 441 and associated coupling arm 465 that attaches the feed roller 441 to the compression roller 442. In an embodiment, the journal 428 of the feed roller 441 may slide along a slot 438 within the coupling arm 465. During the wire loading process, the feed roller 441 may be positioned towards an end of the slot 438 away from the compression roller 442, and the feed roller 441 may be positioned towards the opposite end of the slot 438 towards the feed roller 442 during operation. In an embodiment, a condenser 437 (e.g., a fine pitched comb) may guide wires (not shown in FIG. 4B) from the wire feed system to the feed roller 442 in order to set the wires into corresponding grooves of the feed roller 442 (not visible in FIG. 4B).

The compression roller assembly 440 may also comprise a wire support arm 433. The wire support arm 433 may comprises a pivot point 434 and a tensioning arm 432 that rotates about the pivot point 434. A screw 431 or other mechanism may be used to rotate the tensioning arm 432. A clamp 439 that is towards an end of the tensioning arm 432 may secure the wires (not shown in FIG. 4B), and the rotation of the tensioning arm 432 increases the tension within the wires.

In an embodiment, the compression roller 442 and/or the feed roller 441 maybe heated by a suitable heating system. In one embodiment, embedded heating elements that may be in physical contact with the compression roller 442 and/or the feed roller 441 may be used. Non-contact heating of one or both of the compression roller 442 or the feed roller 441 may also be used. For example, infrared lamps be directed towards one or both of the compression roller 442 or the feed roller 441. The use of non-contact heating process may simplify the design of the compression roller assembly 440 since rotating electrical feedthrough for electrical heating elements may not be needed.

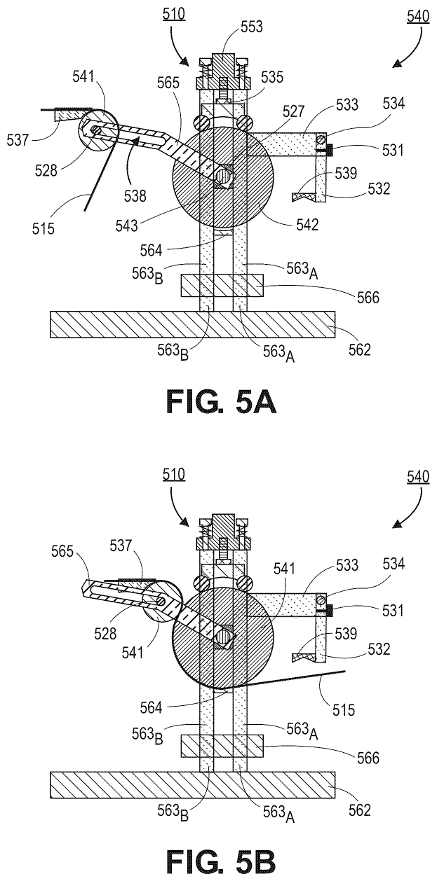

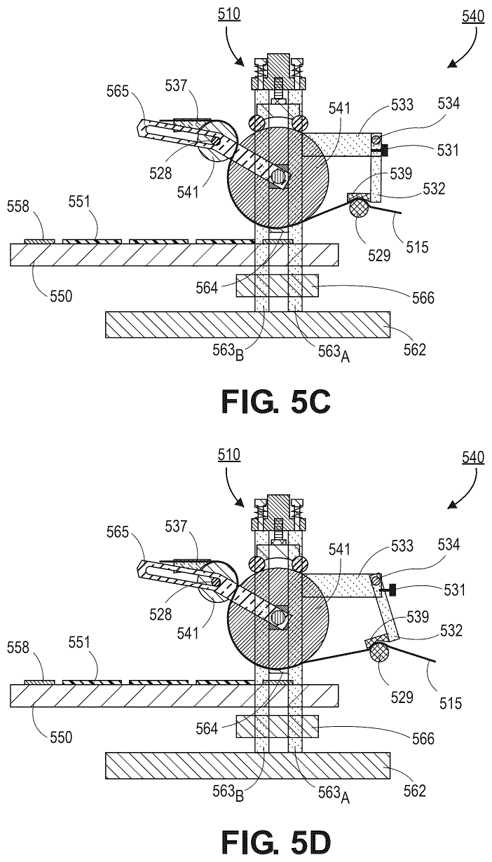

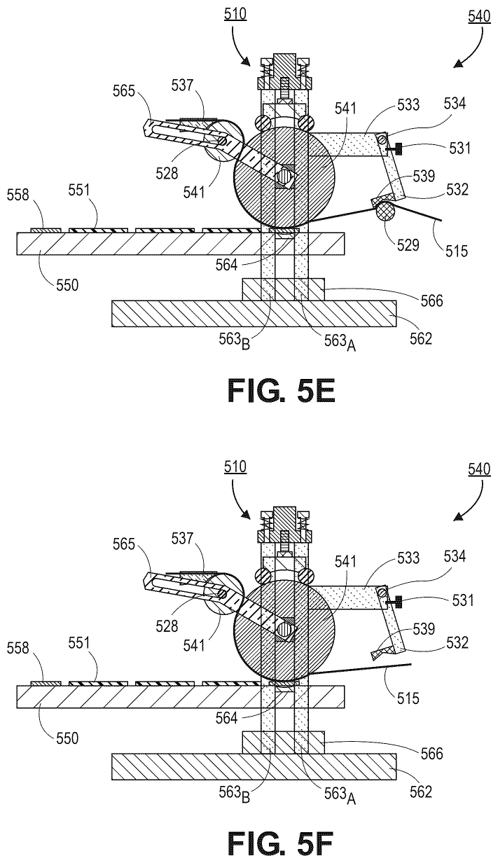

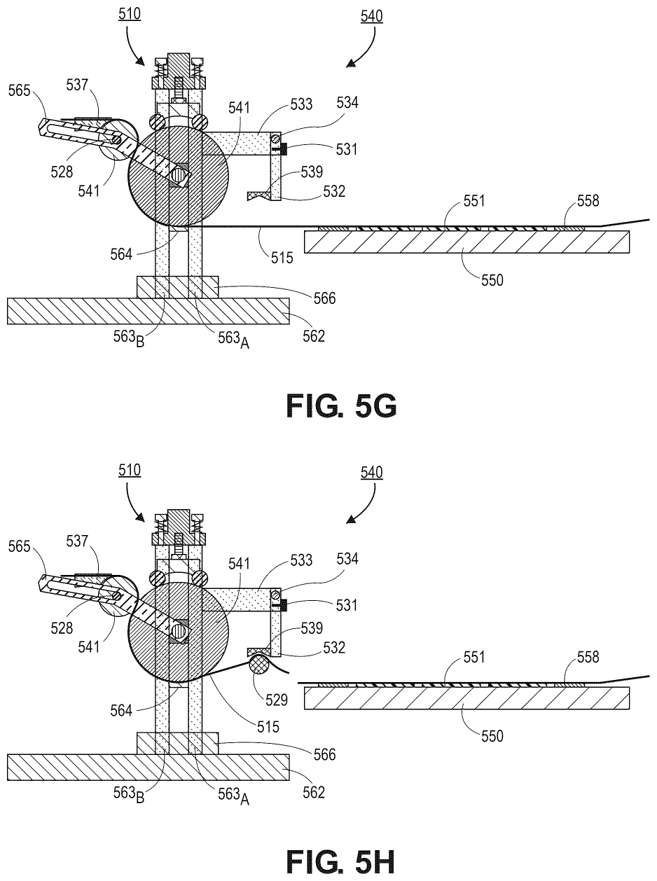

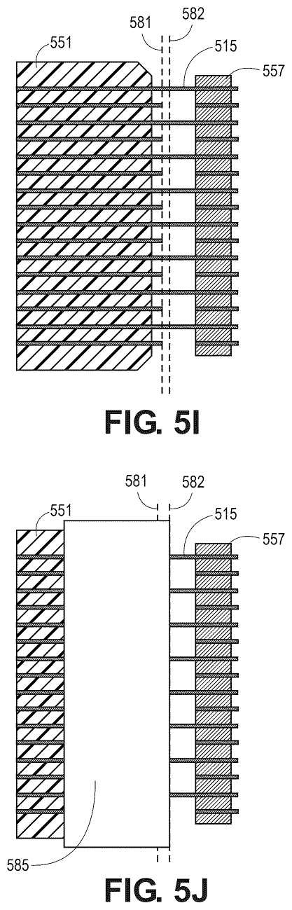

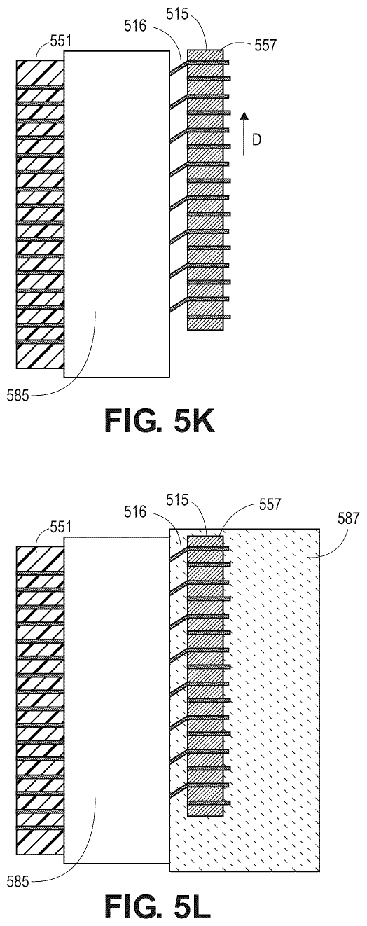

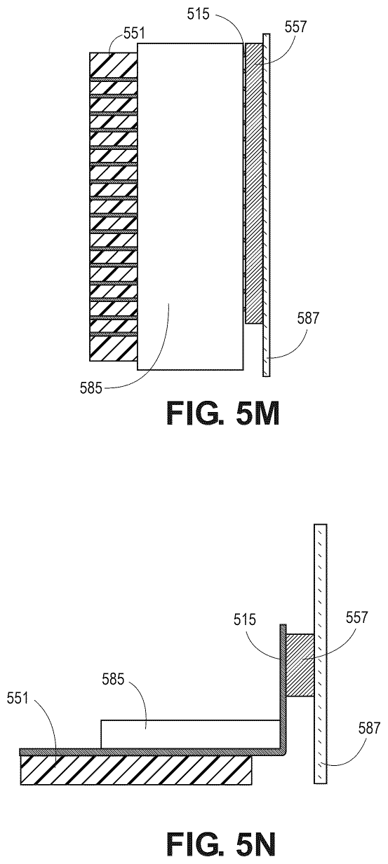

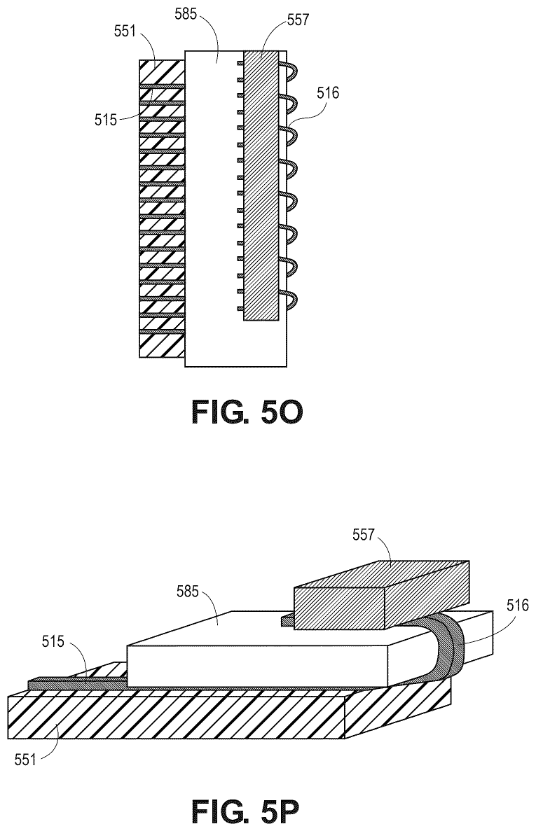

Referring now to FIGS. 5A-5H , a series of side view illustrations that depict a process for bonding wires to substrates with a compression roller assembly 540 is shown, in accordance with an embodiment. In an embodiment, the compression roller assembly 540 may be similar to the compression roller assembly 440 or any other compression roller assembly described herein. For example, a compression roller 542 may be coupled to a frame 563_{A} and 563_{B} by journals 543 that are within journal bearings 527. The frame 563 may be coupled to a roller station 566 and support chassis 562. A roller cradle 564 may support the compression roller 542.

In an embodiment, a wire support arm 533 may be coupled to the frame 563, and the tensioning arm 532 that is rotatable about a pivot point 534 by a screw 531 or the like may be coupled to the wire support arm 533. A clamp 539 may be provided towards an end of the tensioning arm 532.

In an embodiment, a coupling arm 565 may be used to attach a feed roller 541 to the compression roller 542. A journal 528 of the feed roller 541 may fit into a slot 538 of the coupling arm 565 in order to move the feed roller 541 relative to the compression roller 542 for wire 515 loading and/or for wire 515 bonding. A condenser 537 may be provided adjacent to the feed roller 541 to feed the wires 515 into corresponding grooves of the feed roller 541 at a desired pitch.

In an embodiment, a force application assembly 510 that is used to apply a force to the compression roller 542 may be similar to any of the force application assemblies described in greater detail herein. For example, the force application assembly 510 may comprise contact surface bearings that are coupled to a force plate. A load cell 535 may be between the force plate and a press actuator 553, which may comprise one or more spring actuators, a hydraulic press, or the like. While the force application assembly 510 is shown as applying the force directly to the surface of the compression roller 542, other embodiments may comprise the force application assembly 510 applying force to a journal 543 of the compression roller 542. In some embodiments a pair of force application assemblies 510 may be used to provide individual control of the applied force to each end of the compression roller 542.

In FIG. 5A, the wire 515 is beginning to be fed through the compression roller assembly 540. For example, the wire 515 is fed through a channel in the condenser 537 and into a corresponding groove on the feed roller 541. At this point, the feed roller 541 is positioned towards an end of the slot 538 away from the compression roller 542. This may allow for more room to navigate the wire 515 through the system. While a single wire 515 is shown, it is to be appreciated that a plurality of substantially parallel wires 515 (e.g., into and/or out of the plane of FIG. 5A) may be fed into the compression roller assembly 540 substantially simultaneously.

Referring now to FIG. 5B, an illustration of the compression roller assembly 540 after the wire 515 is guided into grooves of the compression roller 542 is shown, in accordance with an embodiment. In an embodiment, the feed roller 541 may be moved along the slot 538 so that the feed roller 541 is proximate to the compression roller 542. Reducing a distance between the feed roller 541 and the compression roller 542 may help to improve alignment of wires 515 as they enter the grooves of the compression roller 542. In an embodiment, the grooves of the feed roller 541 may substantially match the grooves of the compression roller 542 when both the feed roller 541 and the compression roller 542 are at their operating temperatures. That is, the grooves of the feed roller 541 may be substantially aligned and/or at the same pitch as the grooves of the compression roller 542 when both the feed roller 541 and the compression roller 542 are at their operating temperatures. Though, at non-operating temperatures, the alignment and/or pitch of the grooves of the feed roller 541 may be different than the alignment and/or pitch of the grooves of the compression roller 542.

Referring now to FIG. 5C, an illustration of the compression roller assembly 540 after the wire 515 is secured by the clamp 539 and a clamping member 529 is shown, in accordance with an embodiment. Also shown in FIG. 5C is the introduction of a chuck 550 that supports one or more substrates 551 and/or busbars 557. For example, a pair of busbars 557 are provided on opposite ends of a set of three substrates 551. The busbars 557 and substrates 551 may be similar to any of the substrates and/or busbars described in greater detail herein. For example, the substrates 551 may comprise silicon solar cells or the like. In an embodiment, the chuck 550 may be supported over the roller station 566 with rollers, linear guides, or the like (not shown). The compression roller 542 may be supported by the roller cradle 564 above the busbar 557 and/or substrates 551.

Referring now to FIG. 5D, an illustration of the compression roller assembly 540 after the tensioning arm 532 is rotated outwards at the pivot point 534 is shown, in accordance with an embodiment. In an embodiment, the tensioning arm 532 may be rotated out by a screw 531 or any other suitable mechanism.

Referring now to FIG. 5E, an illustration of the compression roller assembly 540 after the compression roller 542 is lowered onto the chuck 550 is shown, in accordance with an embodiment. In an embodiment, the compression roller 542 may rest on the busbar 557. Though, the compression roller 542 may be placed directly on the chuck 550. The compression roller 542 may be lowered by lowering the roller cradle 564. For example, a top of the roller cradle 564 may be moved below a top surface of the chuck 550. When the roller cradle 564 is below the top surface of the chuck 550, the force of the compression roller 542 may be transferred to the busbars 557, the substrates 551, and/or the chuck 550.

Referring now to FIG. 5F, an illustration of the compression roller assembly 540 after the clamp 539 is disengaged is shown, in accordance with an embodiment. For example, when the compression roller 542 presses the wires 515 against the chuck 550, the busbars 557, and/or the substrates 551, the wires 515 retain their tension in the direction that the wires 515 are fed into the system (e.g., to the left of the compression roller 542 in FIG. 5F). Accordingly, the ends of the wires 515 may be released by disengaging the clamp 539.

Referring now to FIG. 5G, an illustration of the compression roller assembly 540 after the chuck 550 is displaced through the compression roller assembly 540 is shown, in accordance with an embodiment. In an embodiment, the wires 515 are bonded to each of the busbars 557 and substrates 551 as a continuous interconnect. As noted above in FIGS. 1A-1C , wires 515 may be cut to provide desired circuitry for a given solar string. In an embodiment, the bonding pressure applied by the compression roller 542 may be uniform during the entire process. Though, embodiments may also benefit from the ability to control the bonding pressure applied by the compression roller 542. Examples of systems and/or methods for providing non-uniform bonding pressures with the compression roller 542 are described in greater detail below. In FIG. 5G, the roller cradle 564 may be raised back up to support the compression roller 542 after the chuck 550 passes by the compression roller 542.

Referring now to FIG. 5H, an illustration of the compression roller assembly 540 after the wire 515 is resecured by the clamp 539 and clamping member 529 is shown, in accordance with an embodiment. In an embodiment the tensioning arm 532 may be reset to its initial position so that the wire 515 may be tensioned again, if needed. The wire 515 on the side of the clamp 539 away from the compression roller 542 may be cut so that the chuck 550 is free to be removed from the continuous roll of wire 515. The process may then continue with a subsequent wire bonding process with operations similar to any of those described with respect to FIGS. 5A-5H . In this way, a substantially continuous wire bonding process for solar cells may be provided. Alternatively, If another chuck 550 is fed into the compression roller 542 immediately behind the first chuck 550, the bonding process may be continuous without the need to re-engage the wire clamp until a controlled machine stop is required.

In some embodiments, the bonded substrates 551 and busbars 557 may be further processed after the wire bonding. For example, it may be desirable to fold the busbars 557 back behind the adjacent substrate 551. This allows the formation of a solar module with a higher efficiency because an area fraction of silicon substrates in the module can be maximized. In order to prevent shorting, the busbar 557 may be insulated from the wires 515 bonded to the back of the solar cell by an insulating layer. In an embodiment, the bend in the wires 515 may also be formed in such a way so that no weak points are formed that might fail in temperature cycling. Accordingly, the busbar 557 may be folded back behind the substrate 551, while also being translated in a direction perpendicular to the wires 515 so that a bend radius of the wire 515 is enlarged. In an embodiment, the exposed wires 515 between the edge of the substrate 551 and the busbar 557 may be spaced a sufficient distance from the front glass to avoid corrosion risk under certain bias conditions. An example of a process for busbar 557 folding is shown with respect to FIGS. 5I-5P.

Referring now to FIG. 5I, a plan view illustration of a portion of a substrate 551 and a busbar 557 is shown, in accordance with an embodiment. In an embodiment, the busbar 557 may be wire bonded to the substrate 551 by wires 515. Every other wire 515 may be trimmed at line 581 in order to provide the desired circuitry for the solar string, as described in greater detail herein. FIG. 5I illustrates a line 582, which may be used as a guideline for the placement of an insulating layer for use during the folding process.

Referring now to FIG. 5J, a plan view illustration of the portion of the substrate 551 after an insulating layer 585 is placed over the backside of the substrate 551 and the wires 515. An edge of the insulating layer 585 may be aligned with the line 582. In some instances, the line 582 may be spaced away from the adjacent edge of the substrate 551 by up to approximately 2.0 mm. For example, the edge of the insulating layer 585 may be between approximately 0.5 mm and approximately 1.0 mm from the adjacent edge of the substrate 551.

In an embodiment, the insulating layer 585 may comprise any electrically insulating material, such as a polymer, a foam, or the like. In some instances, the insulating layer may comprise a plurality of layers. For example, the insulating layer 585 may comprise a polyethylene terephthalate (PET) layer that is provided between a pair of encapsulant layers to form an encapsulant-PET-Encapsulant (EPE) stack or the like. An EPE stack may allow for electrical insulation through the PET layer, while the encapsulation layers provide cushioning for the wires 515 so that the wires 515 are not pulled off of the device side of the cell during thermal cycling. The encapsulation layers may also conform to a topography of the wires 515. The conformal nature of the encapsulation layers may improve subsequent lamination processes since bubbling is avoided since there is a lower chance of there being trapped air around the wires. In an embodiment, the insulating layer 585 may be secured to the substrate 551 with any suitable attachment process. For example, a clamp may hold the insulating layer 585 against the substrate 551 or tape may be used to hold the insulating layer 585 against the substrate 551.

Referring now to FIG. 5K, a plan view illustration of the portion of the substrate 551 after the busbar 557 is displaced in a direction D that is substantially perpendicular to the direction of the wires 515. The displacement of the busbar 557 results in the formation of an angled portion 516 of the wires 515. In an embodiment, the busbar 557 may be displaced up to approximately 5.0 mm. For example, the busbar 557 may be displaced by approximately 3.0 mm.

Referring now to FIG. 5L, a plan view illustration of the portion of the substrate 551 after a folding plate 587 is provided below the busbar 557 is shown, in accordance with an embodiment. In an embodiment, the folding plate 587 may comprise a thin sheet of material that can support the busbar 557 during the folding process.

Referring now to FIG. 5M, a plan view illustration of the substrate 551 after the busbar 557 is folded up to approximately ninety degrees relative to the surface of the substrate 551 is shown, in accordance with an embodiment. As shown, the folding process results in the wires 515 also being directed up along an outer edge of the insulating layer 585.

Referring now to FIG. 5N, a side view illustration of the substrate 551 shown in FIG. 5M is shown, in accordance with an embodiment. As shown, the wire 515 wraps around a corner of the insulating layer 585 and extends up an edge of the insulating layer 585. It is to be appreciated that the wire 515 in FIG. 5N is not entirely within a single plane. For example, a portion of the wire 515 between the right edge of the substrate 551 and the bottom edge of the busbar 557 (as viewed in FIG. 5N) may extend into the plane of FIG. 5N.

Referring now to FIG. 5O, a plan view illustration of the substrate 551 after the folding process is completed is shown, in accordance with an embodiment. As shown, the busbar 557 is now provided above the insulating layer 585 and a portion of the substrate 551. Additionally, the portion 516 of the wire 515 wraps around the edge of the insulating layer 585. As shown, the portion 516 of the wire 515 maybe spaced away from the edge of insulating layer 585. Due to the angle of the portion 516 of the wire 515, the bend radius of the wire 515 is increased. As such, stress and/or other damage to the wire 515 during the folding process is mitigated or eliminated.

Referring now to FIG. 5P, a perspective view illustration of a portion of the substrate 551, insulating layer 558, and busbar 557 after the folding process is shown, in accordance with an embodiment. As shown, the portion 516 of the wire 515 wraps around the edge of the insulating layer 585. In an embodiment, the portion 516 of the wire 515 may be spaced away from the edge of the insulating layer 585 to provide a gentler curve. Additionally, the portion 516 of the wire has a lateral component (with respect to the main direction of the wire 515 coming from the substrate 551) that provides an increase in the bend radius of the wire 515. Stated differently, the portion 516 of the wire 515 that wraps around the edge of the insulating layer 585 has a first end (at the substrate 551) that is in a first plane, and a second end (at the busbar 557) that is in a second plane that is offset, but parallel, to the first plane.

In the process illustrated in FIGS. 5I-5P , the perpendicular displacement of the busbar 557 (shown in FIG. 5K), and the folding process (shown in FIGS. 5M-5O) are described as discrete processing operations. Though, it is to be appreciated that the folding process and the perpendicular displacement of the busbar 557 may be implemented at substantially the same time. Further, embodiments may comprise implementing the process shown in FIGS. 5I-5P manually or with an automated process. For an automated process, appropriate tooling, guides, robotics, imaging, and/or sensing may be developed in order to implement the busbar 557 folding process with minimal human interaction or with no human interaction.

As noted herein, it may be advantageous to rapidly modify a force applied to the compression roller. For example, it may be beneficial to reduce the amount of force applied to the compression roller as the compression roller approaches a trailing edge of the substrate. This helps to prevent over compression at the trailing edge. Similarly, it may be advantageous to rapidly increase the force on the compression roller as the compression roller approaches the leading edge of the substrate. As such, a more uniform amount of force is applied along the entire length of the wire across the substrate (or busbar). In one embodiment, the rapid force control may be achieved using suitably sized industrial electric servo motors with appropriate gearing and closed loop feedback.

Other embodiments may include the use of mechanical displacement of the compression roller. For example, an electrically actuated rotary cam, a wedge mechanism, or the like may be used to vertically displace the compression roller. Yet another embodiment may comprise the use of chucks that include a protruding surface and/or receding surface where changes in force are desired. In an embodiment, the compression roller may also comprise nodes to modify the force applied to the wires.

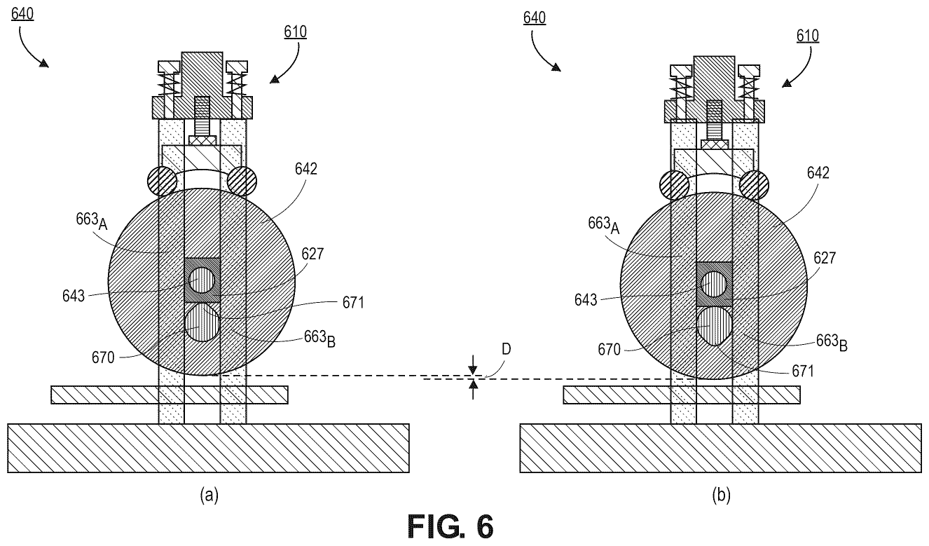

Referring now to FIG. 6, an illustration showing a compression roller assembly 640 with an actuated rotary cam 670 is shown, in accordance with an embodiment. The compression roller assembly 640 may be similar to any of the compression roller assemblies described in greater detail herein. For example, the compression roller assembly 640 may comprise a compression roller 642 that is coupled to a frame 663_{A} and 663_{B} by a journal 643 and a journal bearing 627. A force application assembly 610 may be configured to apply a force on the compression roller 642. The force application assembly 610 may be similar to any of the force application assemblies described in greater detail herein.

The (a) portion of FIG. 6 may comprise a rotary cam 670 that is an actuated position. That is, the lobe 671 (or protrusion) is in contact with the journal bearing 627. This raises the compression roller 642 relative to when the rotary cam 670 is not engaged (e.g., as shown in the (b) portion of FIG. 6). In an embodiment, the offset distance D allows for a different amount of pressure to be applied to the wires between the compression roller 642 and the substrate (not shown). In an embodiment, the rotary cam 670 may be actuated by a motor that rotates the rotary cam 670 when it is desired to change the force applied by the compression roller. This is particularly beneficial since the rapid force change does not need to be implemented by the force application assembly 610, which may be slower and/or more complex.

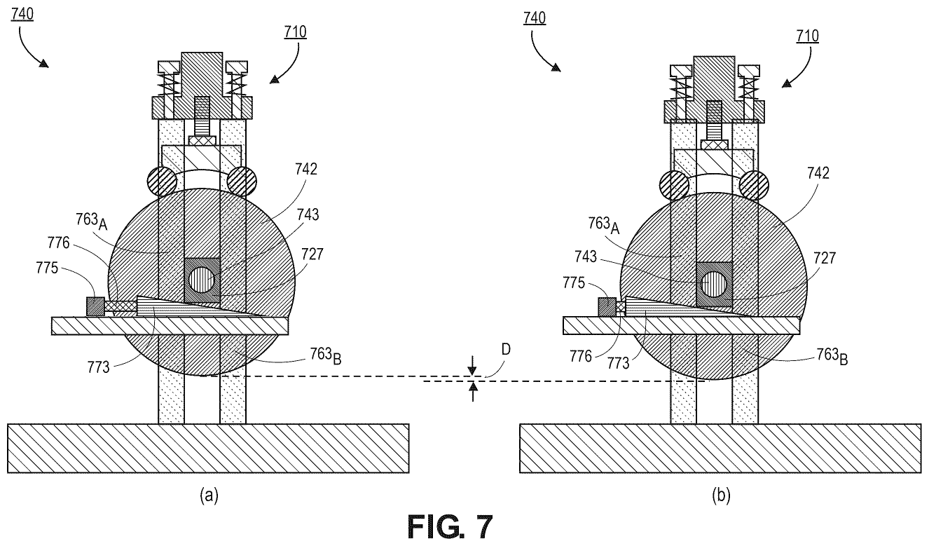

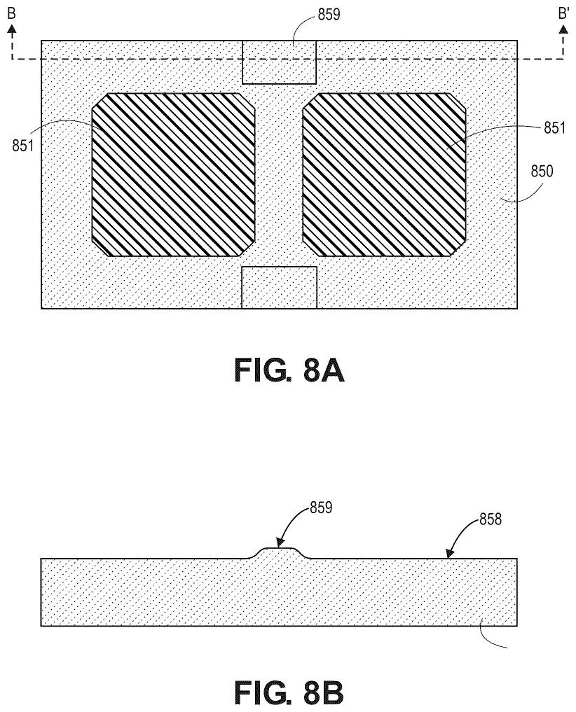

Referring now to FIG. 7, an illustration showing a compression roller assembly 740 with an actuated wedge 773 is shown, in accordance with an embodiment. The compression roller assembly 740 may be similar to any of the compression roller assemblies described in greater detail herein. For example, the compression roller assembly 740 may comprise a compression roller 742 that is coupled to a frame 763_{A} and 763_{B} by a journal 743 and a journal bearing 727. A force application assembly 710 may be configured to apply a force on the compression roller 742. The force application assembly 710 may be similar to any of the force application assemblies described in greater detail herein.

The (a) portion of FIG. 7 may comprise a wedge 773 in a first position. That is, an actuator 775 (e.g., a servo motor) has extended a piston 776 to a first length to provide a first position to the compression roller 742. As the piston 776 extends further, the journal 743 and journal bearing 727 are forced higher up the wedge 773, and the height of the compression roller 742 is increased. As shown in the (b) portion of FIG. 7, the piston 776 is retracted to lower the height of the journal 743 and journal bearing 727 (and, as a result, the compression roller 742). In an embodiment, the offset distance D allows for a different amount of pressure to be applied to the wires between the compression roller 742 and the substrate (not shown). Similar to the use of the rotary cam 670 in FIG. 6, the actuatable wedge 773 is beneficial since the rapid force change can be implemented by an actuator 775 instead of the force application assembly 710, which may be slower and/or more complex.

Referring now to FIGS. 8A and 8B, a plan view illustration (FIG. 8A) of a chuck 850 and a cross-sectional illustration of the chuck 850 along line B-B′ is shown, in accordance with an embodiment. In an embodiment, chuck 850 provides a protrusion 859 up from the surface 858 that forces a vertical displacement of the compression roller as the chuck 850 passes below the compression roller. In the illustrated embodiment, the protrusions 859 are between edges of the substrates 851 and an edge of the chuck 850. Though, one or more protrusions 859 may be provided between two edges of different substrates 851. Additionally, while protrusions 859 are shown in FIGS. 8A and 8B, recessed surfaces may also be used (e.g., to increase the force applied to the wires) in some embodiments.

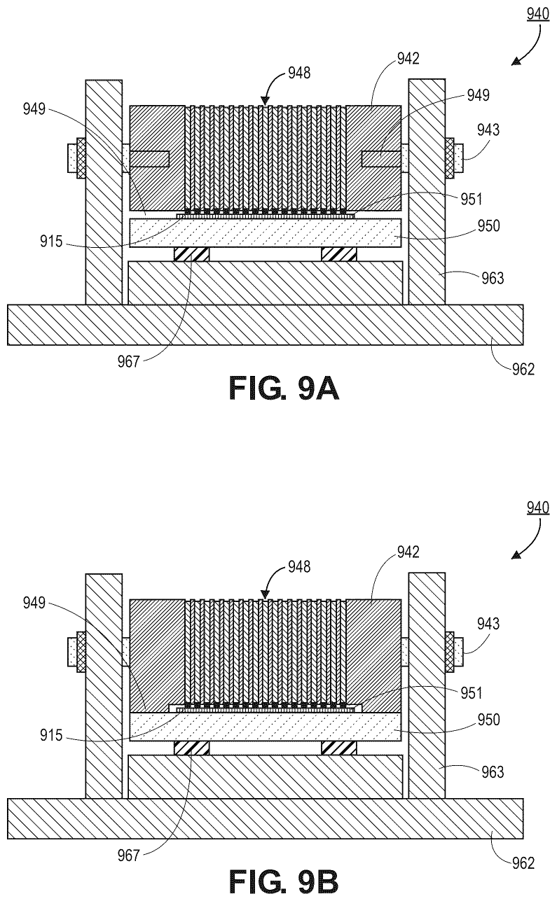

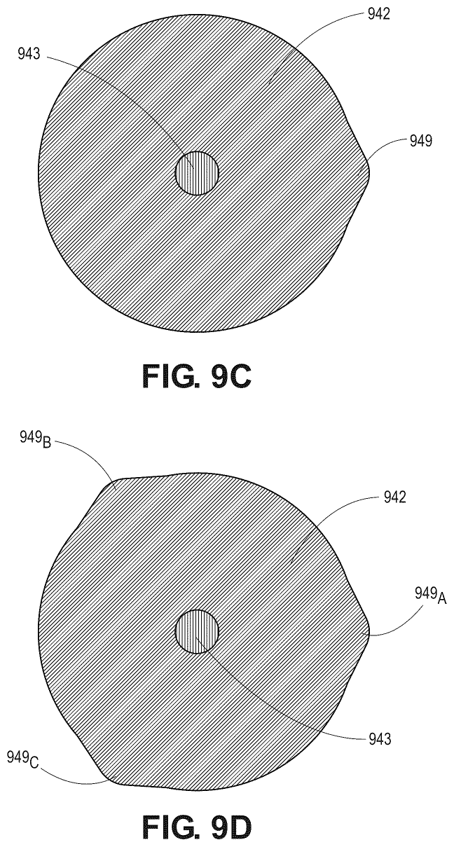

Referring now to FIGS. 9A and 9B, a pair of illustrations that depict a compression roller assembly 940 with a compression roller 942 with a lobe 949 for modifying a force applied to wires 915 is shown, in accordance with an embodiment. In an embodiment, the compression roller assembly 940 may be similar to any of the compression roller assemblies described in greater detail herein. In an embodiment, the compression roller assembly may comprise a compression roller 942 with grooves 948 for retaining a plurality of wires 915 as they are bonded to the substrate 951 over the chuck 950. The compression roller 942 may be coupled to a frame 963 by journals 943. In an embodiment, the chuck 950 may be coupled to a frame 963 and/or chassis 962 by linear guides 967, rollers, or the like.

As shown in FIG. 9A, compression roller 942 is above the surface of the substrate 951 and the chuck 950. That is, substantially all of the downward force of the compression roller 942 is passed into wires 915 to provide a desired bonding force. As shown, the lobe 949 is facing away from the chuck 950. However, in FIG. 9B the lobe 949 is engaged against the chuck 950. This raises the compression roller 942 in the vertical direction and reduces the force transferred into the wires 915. As such, the wires 915 are not compressed as much as in FIG. 9A. For example, the wires 915 in FIG. 9B are taller than the wires 915 in FIG. 9A.

In an embodiment, the position of the lobes 949 may be configured to provided force variation at desired bonding locations on the chuck 950. For example, the lobes 949 may be positioned so that lobes 949 engage the chuck 950 proximate to leading edges and/or trailing edges of substrates 951 and/or busbars.

In FIGS. 9C and 9D side views of compression rollers 942 are shown, in accordance with different embodiments. In FIG. 9C a single lobe 949 is provided on the compression roller 942. In FIG. 9D a plurality of lobes 949 are provided around a perimeter of the compression roller 942. While all of the lobes 949 in FIG. 9D are uniform in shape and have a substantially uniform spacing between each other, embodiments are not so limited. For example, different lobe 949 shapes may be used to apply different force magnitude changes, and/or the spacing between the lobes 949 may be non-uniform.

In embodiments described herein, the inclusion of a non-stick coating on the compression roller may prevent wires from adhering to the compression roller instead of the substrate. Such coatings may include an impingement graphite coating, a molybdenum sulfide-based coating, a plasma deposited hard coating, a sprayed coating or a chemical vapor deposited hard coating. Though, many different coating materials and/or deposition processes may be used in other embodiments.

In a particular embodiment, a coating may also be applied to the compression roller while the compression roller remains in the compression roller assembly. For example, the coating may be applied to the compression roller between bonding operations or during a bonding operation. In an embodiment, the coating may be applied by a spray system, by transferring a solid material onto the roller, or by using a carrier material such as wax to deposit the coating. Embodiments may also comprise applying a carbon powder coating to a roller through the use of a sooty flame exposure to the roller. For example, the flame may be produced by burning acetylene or any other similar hydrocarbons in air.

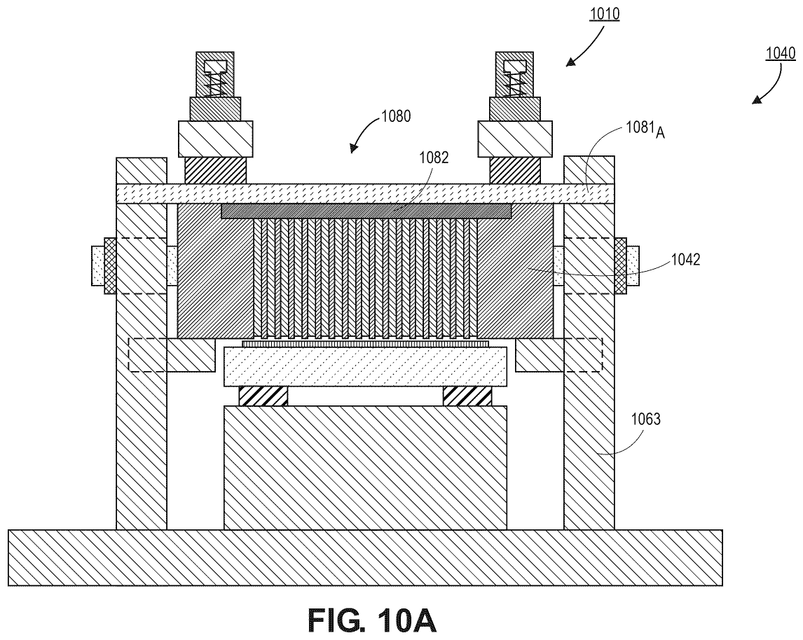

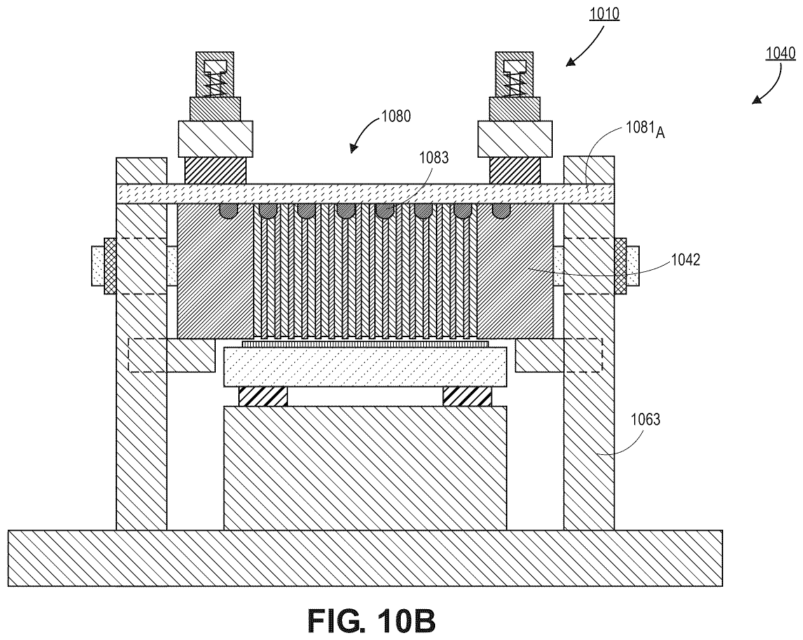

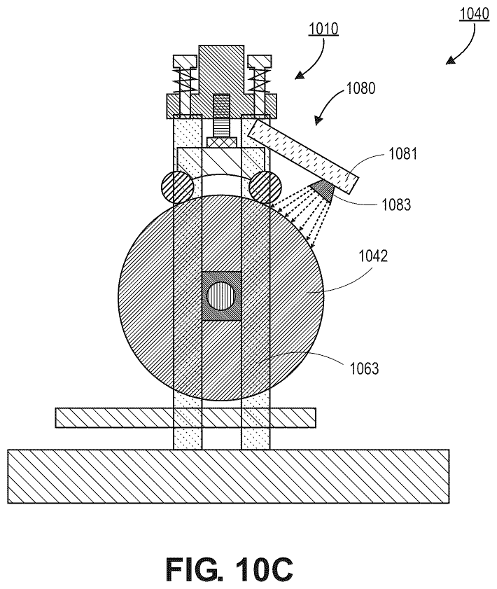

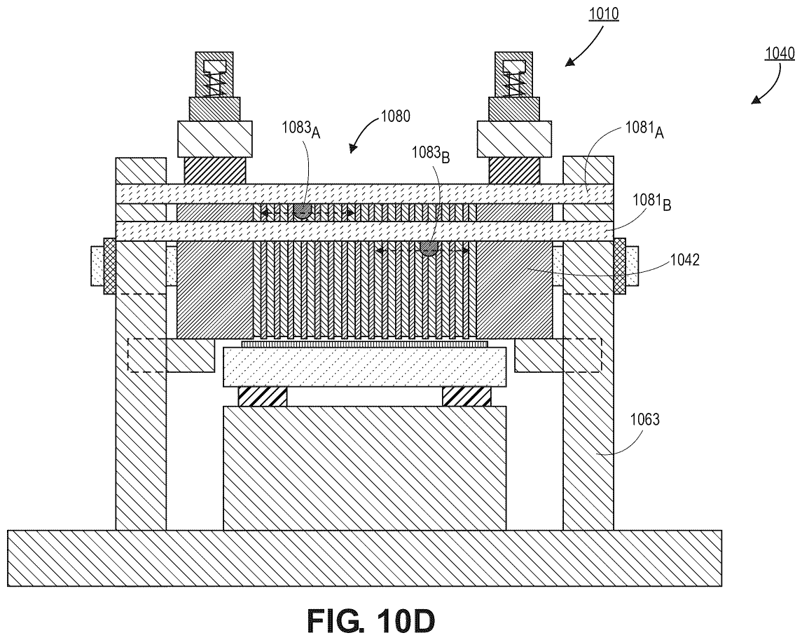

Referring now to FIGS. 10A-10D , a series of illustrations depicting compression roller assemblies 1040 with integrated non-stick coating sprayers 1083 is shown, in accordance with various embodiments. In an embodiment, the compression roller assemblies 1040 may be similar to any of the compression roller assemblies described in greater detail herein. For example, a frame 1063 may support a compression roller 1042, and a force application assembly 1010 may apply a force to the compression roller 1042.

In the embodiment shown in FIG. 10A, a sprayer assembly 1080 is coupled to the frame 1063. For example, a cross-bar 1081 may be coupled to the frame 1063, and a sprayer 1082 may be attached to the cross-bar 1081. Though, it is to be appreciated that sprayer assembly 1080 may position the sprayer 1082 so that the sprayer 1082 sprays a coating onto the compression roller 1042 in any suitable manner. The sprayer 1082 may be fluidically coupled to a supply of coating fluid (not shown) by hoses or the like. In FIG. 10A, a single elongated sprayer 1082 may extend substantially along a width of the compression roller 1042. For example, a width of the sprayer 1082 is greater than a width of the set of grooves on the compression roller 1042.

Referring now to FIG. 10B, an illustration of a compression roller assembly 1040 with a different sprayer assembly 1080 architecture is shown, in accordance with an embodiment. As shown, a plurality of sprayers 1083 are spread across the width of the compression roller 1042. In an embodiment, any number of discrete sprayers 1083 may be used. In some embodiments, all of the sprayers 1083 may spray the same fluid onto the surface of the compression roller 1042. In other embodiments, the plurality of sprayers 1083 may spray two or more different fluids onto the surface of the compression roller 1042.

Referring now to FIG. 10C, a side view illustration of a compression roller assembly 1040 is shown, in accordance with an additional embodiment. As shown, the sprayer 1083 emits a spray towards a surface of the compression roller 1042.

As shown, sprayers 1083 are integrated into the compression roller assembly 1040 so that the non-stick coating may be applied without removing the compression roller 1042 from the compression roller assembly 1040. Materials suitable for spraying include any sprayable material that has a non-stick property, such as graphite in aqueous mixture, a carbon/polymer powder aqueous mixture, boron nitride aqueous mixture and silicone containing aqueous mixture, a silicone oil, or the like. In an embodiment, spraying an aqueous solution on a hot compression roller (e.g., at a temperature of approximately 100° C. or higher), the droplet size of the spray may be small enough and the velocity may be high enough to overcome the Leidenfrost effect. The Leidenfrost effect describes the effect of a droplet bouncing off a hot surface due to the formation of a steam cushion. In some embodiments, a distance between the sprayer 1083 and the surface of the compression roller 1042 may be up to 10 mm, up to 30 mm, or up to 75 mm. Such distances may produce a relatively small deposition spot size on the compression roller 1042 that is approximately 2.0 mm or less, approximately 10 mm or less, or approximately 20 mm or less. In an embodiment, the deposition spot appears as a small area on the roller where there is a liquid puddle in direct contact with the roller surface. In an embodiment, the spray may be applied using an air-atomizing spray, with a small liquid orifice (e.g., which is less than approximately 1.0 mm in diameter). In an embodiment, the sprayers 1083 may comprise fan-style sprayers in order to increase the width of the spray deposition across the face of the compression roller 1042.

Referring now to FIG. 10D, an illustration of a compression roller assembly 1040 with a displaceable sprayer assembly 1080 is shown, in accordance with an embodiment. In an embodiment, the displaceable sprayer assembly 1080 may include one or more sprayers 1083_{A} or 1083_{B} that may be moved in a direction parallel to the axis of the compression roller 1042. For example, the sprayers 1083 may move along the cross-bars 1081_{A} or 1081_{B}, as indicated by the arrows. In an embodiment, the sprayers 1083 may move back and forth while the compression roller 1042 is rotating to create a coating that has spiral pattern. A pitch of the spiral pattern may be set such that the spray is re-deposited on the same portion of the roller again after it has worn off. A number of sprayers 1083 may be chosen such that an entire surface of the compression roller may be coated before the coating has worn off the first areas that were coated in order to enable a continuous recoating process.

In some embodiments, the compression roller 1042 may be pre-coated at a lower temperature with a spray or different method to increase the infrared emissivity of the roller during hot coating. The infra-red radiation from the compression roller 1042 may help to heat the spray before it reaches the surface of the compression roller 1042. This may improve the retention of the spray puddle on the compression roller 1042 surface. Additional heating may be provided to the compression roller 1042 to compensate for heat that is lost to vaporization of the spray and/or air cooling from the spray.

Infra-red imaging metrology may be used to monitor a thickness of a coating on the compression roller 1042. As the coating wears off, the emissivity of the surface of the compression roller 1042 decreases, which is visible as a reduction in infrared radiation intensity.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a first roller with a plurality of first grooves;
a force application assembly configured to apply a force to the first roller;
a frame configured to retain the first roller, wherein the first roller is displaceable in a vertical direction along the frame; and
a second roller coupled to the first roller, wherein the second roller comprises a plurality of second grooves, and wherein the plurality of first grooves are aligned with the plurality of second grooves.

2. The apparatus of claim 1, wherein the first roller comprises journals that engage journal bearings on the frame.

3. The apparatus of claim 1, wherein the force application assembly comprises:
a press actuator;
a force plate; and
a contact surface bearing.

4. The apparatus of claim 3, wherein the force application assembly further comprises:
a second press actuator;
a second force plate; and
a second contact surface bearing.

5. The apparatus of claim 3, wherein the press actuator comprises a spring, a servo motor, or a hydraulic press.

6. The apparatus of claim 3, wherein the force application assembly further comprises a load cell.

7. The apparatus of claim 3, wherein the contact surface bearing contacts the first roller.

8. The apparatus of claim 7, wherein the contact surface bearing contacts a journal of the first roller.

9. The apparatus of claim 1, wherein the second roller is coupled to the first roller by a coupling arm.

10. The apparatus of claim 9, wherein the second roller comprises a journal that is set into a slot of the coupling arm, and wherein the second roller is displaceable along a length of the slot.

11. The apparatus of claim 1, further comprising:
a wire tensioning arm coupled to the frame.

12. The apparatus of claim 1, further comprising:
a rotary cam configured to displace the first roller vertically along the frame in a cyclical manner.

13. The apparatus of claim 12, wherein the rotary cam comprises a plurality of lobes.

14. The apparatus of claim 1, further comprising:
a wedge to displace the first roller vertically along the frame.

15. An apparatus, comprising:
a substrate, wherein the substrate comprises a solar cell;
a wire electrically coupled to the solar cell of the substrate;
an insulating layer over the wire, wherein the wire wraps around an edge of the insulating layer, and wherein a gap is provided between the wire and the edge of the insulating layer;
a busbar over the insulating layer, wherein the wire is coupled to the busbar, and wherein the wire is between the busbar and the insulating layer.

16. The apparatus of claim 15, wherein a first horizontal portion of the wire on a surface of the substrate is offset from a second horizontal portion of the wire on the insulating layer.

17. The apparatus of claim 16, wherein the offset is up to 5.0 mm.

18. The apparatus of claim 15, wherein the insulating layer comprises a polyethylene terephthalate (PET) layer that is provided between a pair of encapsulant layers.

19. The apparatus of claim 18, wherein the encapsulant layers conform to the wire.

20. The apparatus of claim 15, a second wire between the busbar and the insulating layer, wherein the second wire terminates before wrapping around the edge of the insulating layer.
